(19) United States
(12) Patent Application Publication
(10) Pub. No.: US 2014/0171009 A1
(43) Pub. Date: Jun. 19, 2014

(54) Radio Frequency Receiver

(71) Applicant: Huawei Technologies Co., Ltd., Shenzhen (CN)

(72) Inventors: Massoud Tohidian, Delft (NL); Iman Madadi, Delft (NL); Robert Bogdan Staszewski, Delft (NL)

(73) Assignee: Huawei Technologies Co., Ltd., Shenzhen (CN)

(21) Appl. No.: 14/145,316

(22) Filed: Dec. 31, 2013

Related U.S. Application Data
(63) Continuation of application No. PCT/EP2012/062030, filed on Jun. 21, 2012.

(51) Int. Cl. H03D 7/14

(52) U.S. Cl. CPC H03D 7/14
USPC 455/326

(57) ABSTRACT

A radio frequency receiver for receiving an analog radio frequency signal, the radio frequency receiver comprising a sampling mixer being configured to sample the analog radio frequency signal using a predetermined sampling rate (fₛ) to obtain a discrete-time signal, and to shift the discrete-time signal towards an intermediate frequency to obtain an intermediate discrete-time signal sampled at the predetermined sampling rate (fₛ), and a processing circuit for discrete-time processing the intermediate discrete-time signal at the predetermined sampling rate (fₛ).

### CROSS-REFERENCE TO RELATED APPLICATIONS

This application is a continuation of International Application No. PCT/EP2012/062030, filed on Jun. 21, 2012, which is hereby incorporated by reference in its entirety.

### BACKGROUND

The present invention relates to a radio frequency receiver and a method for receiving an analog radio frequency (RF) signal.

Receivers are electronic circuits that receive RF signal at high frequency and down-convert it to baseband for further processing and demodulation. They usually amplify the weak desired RF signal and filter undesired adjacent signals and blockers around. A receiver is commonly tunable by changing the frequency of its local oscillator (LO) to receive a specific channel in a certain band.

Multi-band receivers are able to receive a signal from two or more different bands located at different frequencies. Since these bands might be located far from each other, a multi-band receiver should be tunable or programmable to cover all desired bands.

A multi-standard receiver can receive signals in different standards. One of the main differences between these standards is signal bandwidth. Therefore, bandwidth of a multi-standard receiver must be selectable to cover different standards. However, other requirements of receiver such as receiving frequency, sensitivity, linearity, filtering requirement, etc. might be different in different standards. Rather than including multiple different receivers for different bands or standards, a single multi-band/multi-standard receiver might be used with programmable receiving frequency and input bandwidth.

The conventional superheterodyne receiver architecture 1100 as illustrated in FIG. 11 provides high quality filtering at intermediate frequency (IF), flicker-free gain at IF but applies fixed intermediate frequency. A received radio frequency signal with frequency f_{RF}=f_{LO}+/−f_{IF} in the superheterodyne receiver architecture 1100 passes a pre-select stage 1101, a low noise amplifier (LNA) 1103, an RF mixer 1105, an intermediate frequency (IF) filter 1107, an IF amplifier 1109, an IF mixer 1111, a channel selector 1113, a baseband gain stage 1115 and analog-to-digital converter (ADC) 1117 before it is passed to the digital baseband processor modem 1119 for further processing.

However, due to the lack of the quadrature operation of mixers 1205 (1105 on FIG. 11) multiplying the desired band of frequency ω₁ with the LO frequency ω_{LO} as depicted in the frequency diagram 1200 of FIG. 12, images 1203 of the desired band 1201 are aliased at IF resulting in undesired aliasing components 1209 in IF band of frequency ω_{IF}. A low pass filter (LPF) 1207 is used to remove the high-frequency summing terms of the mixing process.

Receivers should support a multi-band multi-standard operation to cover a wide range of communication standards. On the other hand, to be cost effective, it is desired to highly integrate it as a single chip preferably in a nano-scale Complementary Metal-Oxide-Semiconductor (CMOS) process. Homodyne architecture (including Zero Intermediate Frequency (ZIF) and Low Intermediate Frequency (LIF)) is a common receiver structure due to its well-recognized capability of monolithic integration. FIG. 13 illustrates a common homodyne receiver architecture 1300. A received radio frequency signal with frequency f_{RF}=f_{LO} in the homodyne receiver architecture 1300 passes a pre-select stage 1301, a low noise amplifier 1303, a mixer 1305, a channel selector 1307, a baseband gain stage 1309 and an analog-to-digital converter 1311 before it is passed to the digital baseband processor modem 1313 for further processing.

However, the homodyne receiver architecture 1300 suffers from several technical problems that require special attention to make this architecture suitable for different communication standards. Different interference phenomena are illustrated in FIG. 14 depicting a homodyne receiver with a low noise amplifier 1401, a mixer 1403, a low pass filter 1405, a gain stage 1407, and an analog-to-digital converter 1409.

Direct Current (DC) offset is a common problem in ZIF structure caused by self-mixing of the LO signal cos ω_{LO}t amplified, or not amplified, through the LNA 1401 or strong interferer at the down-converting mixer 1403 as illustrated in FIG. 14. It would be worse if LO leakage reaches the antenna and is reflected by the surroundings. In this case, it will cause time-varying DC offset dependent on the ever-varying antenna environment. Therefore, normally DC offset cancellation techniques need to be used for ZIF or low intermediate frequency (LIF). Since LO frequency is substantially the same as input RF frequency, the LO leakage can be higher than in case of a receiver with different LO frequency. In some cases, LO leakage calibration is needed. Also, second-order intermodulation (IM2) is a common problem in ZIF, which usually needs second order intercept point (IP2) calibration. In the ZIF structure, normally a small part of receiver gain is provided at RF stage and the major part is provided at baseband (BB) stages. Therefore, flicker noise of baseband (BB) amplifier increases the total noise figure (NF) of the system. Designers usually try to minimize it by using large transistor sizes in BB. Moreover, since the first filtering is performed in BB and considering the RF gain before BB, the first BB filter has to be highly linear. Operational amplifier (opamp)-based or Gm-C based biquad filter is a well-known block for this purpose but it consumes high power.

Superheterodyne architecture as depicted in FIG. 15 has been recognized to solve the above problems. A received radio frequency signal with frequency f_{RF}=f_{LO}+/−f_{IF} in the superheterodyne receiver architecture 1500 passes a pre-select stage 1505, a low noise amplifier 1507, an RF mixer 1509, an external (off-chip) intermediate frequency (IF) filter 1503, an IF amplifier 1511, an IF mixer 1513, a channel selector 1515, a baseband gain stage 1517 and an analog-to-digital converter 1519 before it is passed to the digital modem 1521 for further processing.

However, the conventional superheterodyne architecture 1500, as depicted in FIG. 15, introduces its own set of problems. The IF filter 1503 or multiple thereof, are conventionally implemented as off-chip components, which are costly. Then high power for I/O buffers is needed to drive the off-chip IF filter 1503. Further, the off-chip IF filter 1503 is only accessible through bond wires, which provide parasitic inductance and capacitance. In addition, the receiver with a fixed frequency IF filter requires two independent local oscillators: one to down-convert from RF to IF and another one to down-convert from IF to BB.

### SUMMARY

It is the object of the invention to provide a concept for a radio frequency receiver providing improved noise rejection, flexible bandwidth filtering and efficient implementation.

This object is achieved by the features of the independent claims. Further implementation forms are apparent from the dependent claims, the description and the figures.

The invention is based on the finding that a discrete-time receiver front-end with high sampling rate at RF input with deferred decimation improves the noise floor of the received signal. The received signal is oversampled at RF stage and this high sampling rate is maintained at least after the first discrete time (DT) filter. This is feasible and preferable in nano-scale CMOS with transistors acting as very fast switches and with high density capacitors such as metal-oxide-metal (MoM), and metal-oxide-semiconductor (MOS). The discrete-time receiver front-end can be employed in both receiver architectures, homodyne (low-IF) and superheterodyne (high-IF) receivers.

The invention is further based on the finding that a radio frequency receiver applying high sampling rate at RF input with deferred decimation provides excellent image rejection and is easy to implement. By employing image reject topology for the mixers, a full rate Infinite Impulse Response (IIR) filter at IF stage can be used for filtering out alias frequencies of the IF mixer. By using variable high-IF frequency, e.g. sliding IF, one LO is sufficient for the whole receiver providing flexible bandwidth filtering. A powerful discrete-time baseband filtering before delivering the receive signal to ADC further improves image rejection.

In order to describe the invention in detail, the following terms, abbreviations and notations will be used:

RF: radio frequency,

IF: intermediate frequency,

ZIF: zero intermediate frequency,

LIF: low intermediate frequency,

LO: local oscillator,

BB: baseband,

BW: bandwidth,

LPF: low-pass filter,

BPF: band-pass filter.

According to a first aspect, the invention relates to a radio frequency receiver for receiving an analog radio frequency signal, the radio frequency receiver comprising: a sampling mixer being configured to sample the analog radio frequency signal using a predetermined sampling rate to obtain a discrete-time signal, and to shift the discrete-time signal towards an intermediate frequency to obtain an intermediate discrete-time signal sampled at the predetermined sampling rate; and a processing circuit for discrete-time processing the intermediate discrete-time signal at the predetermined sampling rate.

By using a radio frequency receiver according to the first aspect, disadvantages of both ZIF (including LIF) and superheterodyne architectures can be avoided. The radio frequency receiver according to the first aspect of the invention is insensitive to 2nd-order nonlinearities.

In a first possible implementation form of the radio frequency receiver according to the first aspect, the predetermined sampling rate is an oversampling rate with an oversampling factor, which is at least 2 or at least 4 with respect to a frequency (f_{LO}) of a local oscillator of the sampling mixer (101).

A radio frequency receiver according to the first implementation form of the first aspect can provide substantially reduced LO leakage to antenna.

In a second possible implementation form of the radio frequency receiver according to the first aspect as such or according to the first implementation form of the first aspect, the sampling mixer is a direct-sampling mixer.

The direct-sampling mixer can be advantageous in regarding a tradeoff between noise figure and distortion characteristics.

In a third possible implementation form of the radio frequency receiver according to the first aspect as such or according to any of the previous implementation forms of the first aspect, the sampling mixer is configured to oversample the analog radio frequency signal with an oversampling rate and to provide a number of discrete-time sub-signals collectively representing the discrete-time signal, each discrete-time sub-signal representing the analog radio frequency signal sampled with a sampling rate corresponding to a frequency of a local oscillator.

A radio frequency receiver according to the third implementation form of the first aspect solves the time varying DC offset problem and is insensitive to the flicker noise. The flicker noise typically gets worse with CMOS scaling, thereby presenting severe impediments to the integration progress, which are solved when using the radio frequency receiver according to the third implementation form of the first aspect.

In a fourth possible implementation form of the radio frequency receiver according to the first aspect as such or according to any of the previous implementation forms of the first aspect, the sampling mixer is a quadrature mixer comprising an in-phase path and a quadrature path.

A radio frequency receiver according to the fourth implementation form of the first aspect can provide an improved leakage suppression.

In a fifth possible implementation form of the radio frequency receiver according to the fourth implementation form of the first aspect, the in-phase path is configured to generate an in-phase oscillator signal with the repeating function [1 0 −1 0] and the quadrature phase path is configured to generate a quadrature phase oscillator signal with the repeating function [0 1 0−1].

The repeating functions [1 0 −1 0] and [0 1 0−1] are easy to implement as they consist of only three different numbers.

In a sixth possible implementation form of the radio frequency receiver according to the fourth implementation form of the first aspect, the in-phase path is configured to generate an in-phase oscillator signal with the repeating function [1 1+√2 1+√2 1 −1 −1−√2 −1−√2 −1] and the quadrature phase path is configured to generate a quadrature phase oscillator signal with the repeating function [−1−√2 −1 1 1+√2 1+√2 1 −1 −1−√2].

The repeating functions [1 1+√2 1+√2 1 −1 −1−√2 −1−√2 −1] and [−1−√2 −1 1 1+√2 1+√2 1 −1 −1−√2] are easy to implement as they consist of only four different numbers.

In a seventh possible implementation form of the radio frequency receiver according to the first aspect as such or according to any of the previous implementation forms of the first aspect, the processing circuit comprises an in-phase path coupled to an in-phase path of the sampling mixer, and a quadrature path coupled to a quadrature path of the sampling mixer.

The processing circuit is coupled to the sampling mixer and operates at the same sampling rate as the sampling mixer thereby facilitating design of the radio frequency receiver.

In an eighth possible implementation form of the radio frequency receiver according to the first aspect as such or according to any of the previous implementation forms of the first aspect, the processing circuit comprises a channel selector.

Thus, the radio frequency receiver is able to receive a signal from two or more different bands located at different frequencies. The radio frequency receiver is flexible for selecting the desired channel.

In a ninth possible implementation form of the radio frequency receiver according to the first aspect as such or according to any of the previous implementation forms of the first aspect, the processing circuit comprises a discrete-time filter being configured to filter the intermediate discrete-time signal at the predetermined sampling rate.

A radio frequency receiver according to the ninth possible implementation form is flexible for performing filter requirements of different standards.

In a tenth possible implementation form of the radio frequency receiver according to the first aspect as such or according to any of the previous implementation forms of the first aspect, the discrete-time filter is a low-pass filter or band-pass filter, in particular a complex band-pass filter.

A radio frequency receiver according to the tenth implementation form is able to filter a baseband signal as well as an intermediate frequency signal.

In an eleventh possible implementation form of the radio frequency receiver according to the first aspect as such or according to any of the previous implementation forms of the first aspect, the processing circuit is configured to perform a charge sharing between an in-phase and a quadrature component of the intermediate discrete-time signal.

A radio frequency receiver performing charge sharing can be space-efficiently designed and can be integrated on a single chip.

In a twelfth possible implementation form of the radio frequency receiver according to the first aspect as such or according to any of the previous implementation forms of the first aspect, the processing circuit comprises a switched capacitor circuit.

Switched capacitor circuits are more suitable for use within integrated circuits, where accurately specified resistors and capacitors are not economical to construct.

In a thirteenth possible implementation form of the radio frequency receiver according to the first aspect as such or according to any of the previous implementation forms of the first aspect, the intermediate frequency is zero within a zero frequency region.

A radio frequency receiver with intermediate frequency being zero can be efficiently implemented on a chip as the extra mixing stage for the intermediate frequency can be omitted.

In a fourteenth possible implementation form of the radio frequency receiver according to the first aspect as such or according to any of the previous implementation forms of the first aspect, the radio frequency receiver further comprises an analog amplifier arranged upstream of the sampling mixer.

The analog amplifier provides for improved dynamics and higher precision of the radio frequency receiver.

A radio frequency receiver according to the first aspect of the invention can be fully integrated without an off-chip IF filter, thus it is a low cost receiver. As filtering bandwidth can be precisely selected with capacitor ratio and clock rate, the radio frequency receiver according to aspects of the invention is less sensitive to process-voltage-temperature (PVT). The receiver's

IF frequency is selectable. For example, for a given input RF frequency, IF can be selected between f_{LO}/4, f_{LO}/8, f_{LO}/16 etc. This capability allows changing IF from one to another in a busy environment to tolerate more powerful blocker signals. Discrete-time signal processing can be done by switches and capacitors. The more the advanced technology is, the faster switches the switches are and the higher the capacitor density is. Therefore, it is process scalable with Moore's law.

The superior structure of a radio frequency receiver according to the first aspect of the invention allows using simple inverter-based gₘ stage instead of complex opamp-based structures for signal processing and filtering. This results in lower power consumption.

According to a second aspect, the invention relates to a method for receiving an analog radio frequency signal, the method comprising: sampling the analog radio frequency signal using a predetermined sampling rate to obtain a discrete-time signal, and shifting the discrete-time signal towards an intermediate frequency to obtain an intermediate discrete-time signal sampled at the predetermined sampling rate; and discrete-time processing the intermediate discrete-time signal at the predetermined sampling rate.

### BRIEF DESCRIPTION OF THE DRAWINGS

Further embodiments of the invention will be described with respect to the following figures, in which:

FIG. 1 shows a block diagram of a radio frequency receiver according to an operational form;

FIG. 2 shows a block diagram of a radio frequency receiver according to an operational form;

FIG. 3 shows a block diagram of a discrete-time filter of a processing circuit of a radio frequency receiver according to an operational form;

FIG. 4 shows a set of switching signals for controlling the switches of a discrete-time filter according to an operational form;

FIG. 5 shows a SIMULINK™ model of a radio frequency receiver according to an operational form;

FIG. 6 shows a performance diagram of a radio frequency receiver according to an implementation;

FIG. 7 shows a performance diagram of a radio frequency receiver according to an implementation;

FIG. 8 shows a block diagram of an analog amplifier of a radio frequency receiver in continuous-time representation according to an operational form;

FIG. 9 shows a block diagram of an analog amplifier of a radio frequency receiver in discrete-time representation according to an operational form;

FIG. 10 shows a schematic diagram of a method for receiving an analog radio frequency signal according to an operational form;

FIG. 11 shows a block diagram of a conventional superheterodyne receiver architecture;

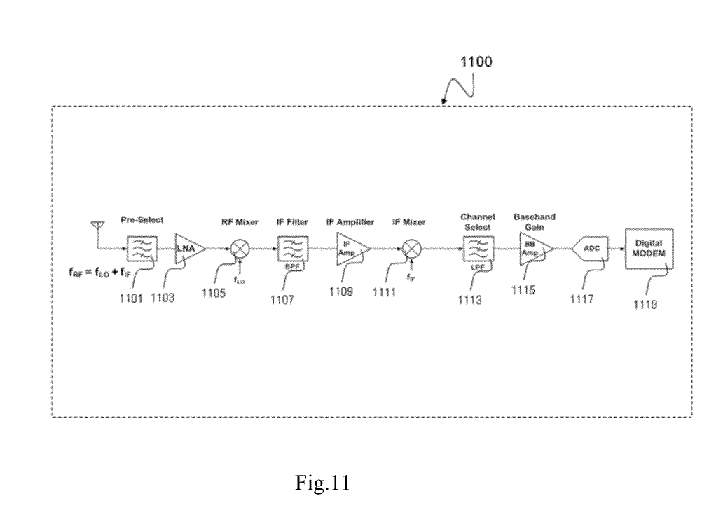

FIG. 12 shows a frequency diagram of a received signal in a conventional superheterodyne receiver architecture;

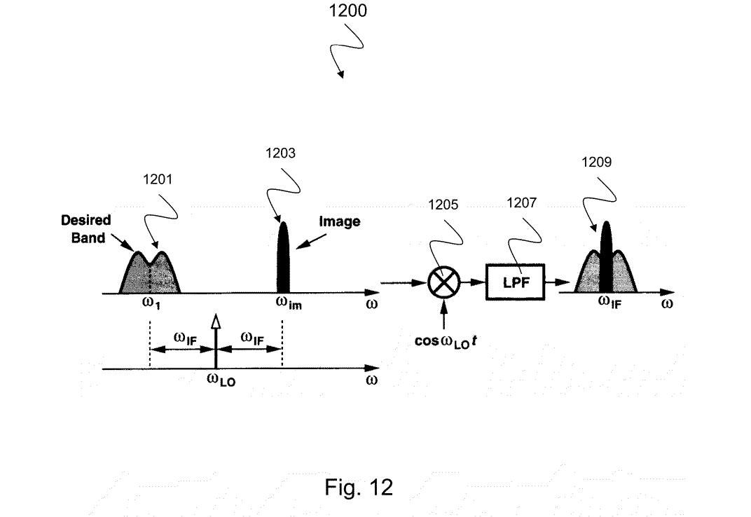

FIG. 13 shows a block diagram of a conventional homodyne receiver architecture;

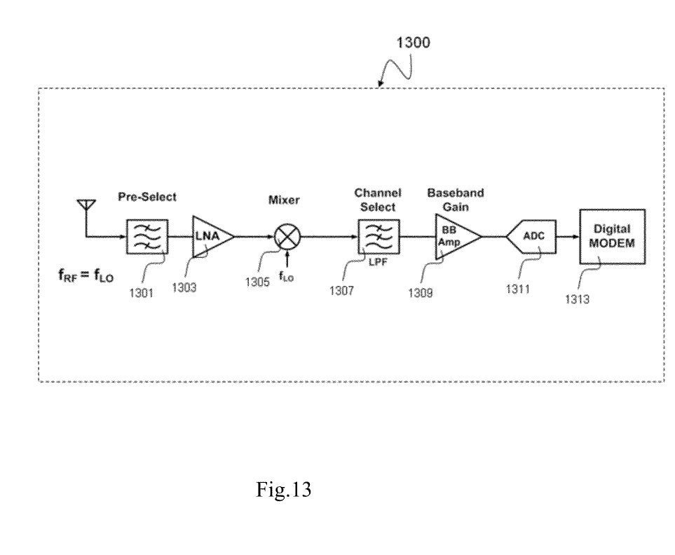

FIG. 14 shows a frequency diagram of a received signal in a conventional homodyne receiver architecture; and

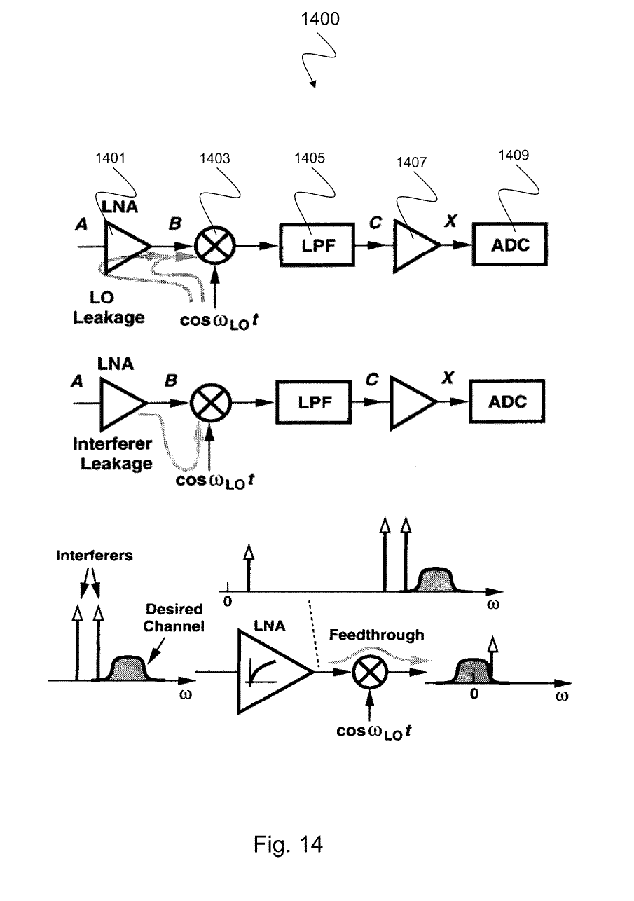

FIG. 15 shows a block diagram of a conventional superheterodyne receiver architecture with off-chip IF filtering.

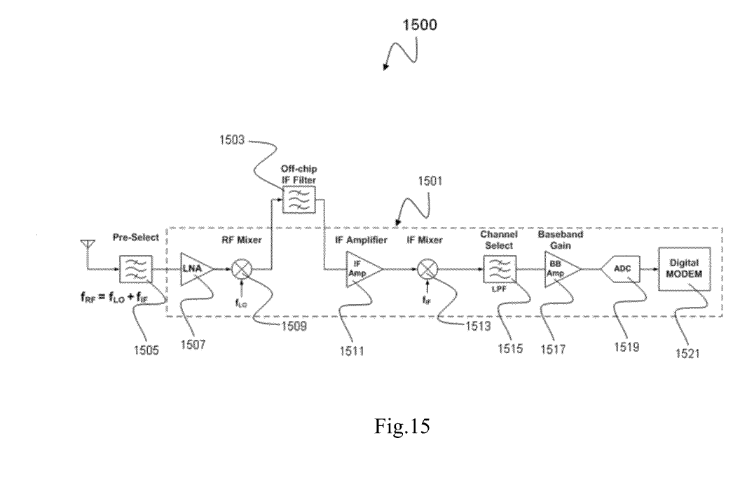

### DETAILED DESCRIPTION OF EMBODIMENTS

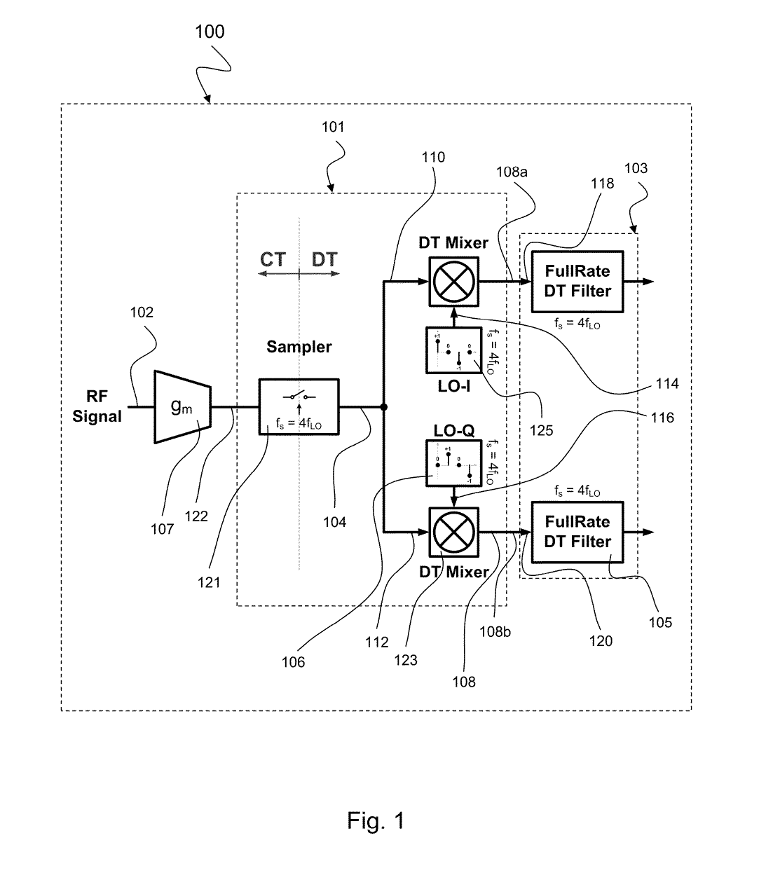

FIG. 1 shows a block diagram of a radio frequency receiver 100 according to an operational form. The radio frequency receiver 100 is configured for receiving an analog radio frequency signal 102. The radio frequency receiver 100 comprises a sampling mixer 101, a processing circuit 103 and an analog amplifier 107.

The sampling mixer 101 is configured to sample the analog radio frequency signal 102 using a predetermined sampling rate fₛ to obtain a discrete-time signal 104, and to shift the discrete-time signal 104 towards an intermediate frequency f_{IF}=|f_{RF}−f_{LO}| to obtain an intermediate discrete-time signal 108 sampled at the predetermined sampling rate fₛ. The processing circuit 103 is configured for discrete-time processing the intermediate discrete-time signal 108 at the predetermined sampling rate fₛ.

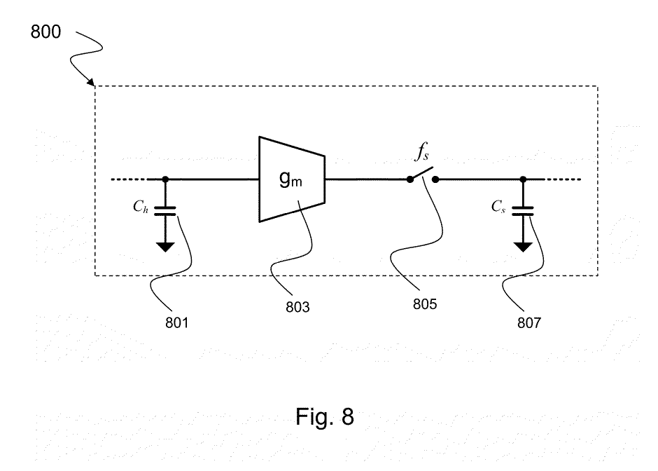

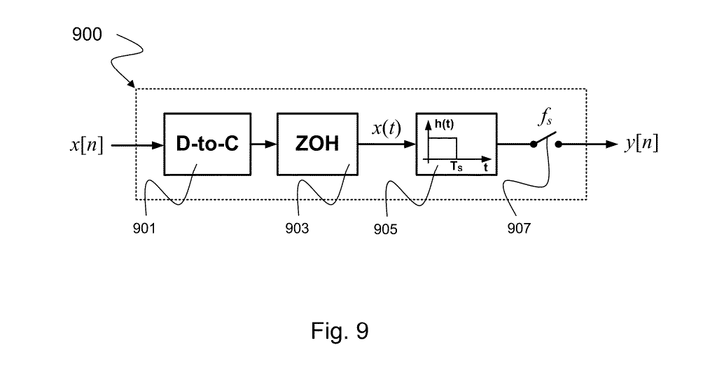

The analog amplifier 107 is configured to receive and amplify the analog radio frequency signal 102 providing an amplified analog radio frequency signal 122. The sampling mixer 101 is coupled to the analog amplifier 107 and is configured to receive the amplified (through transconducting amplification) analog radio frequency signal 122 from the analog amplifier 107. In an operational form, the analog amplifier 107 comprises a gₘ stage as described below with respect to FIGS. 8 and 9.

The sampling mixer 101 is a quadrature mixer comprising an in-phase path 110 and a quadrature path 112. The sampling mixer 101 comprises a sampler 121 and a quadrature discrete-time mixer 123. The sampler 121 is configured to sample the amplified analog radio frequency signal 122 providing the discrete-time signal 104. An in-phase part of the quadrature discrete-time mixer 123 is configured to mix the discrete-time signal 104 with an in-phase oscillator signal 114 generated by a local oscillator 125. A quadrature part of the quadrature discrete-time mixer 123 is configured to mix the discrete-time signal 104 with a quadrature oscillator signal 116 generated by the local oscillator 106. In an operational form, the sampling mixer 101 is a direct-sampling mixer. In an operational form, the sampling mixer 101 is configured to oversample the analog radio frequency signal 102 with an oversampling rate and to provide a number of discrete-time sub-signals collectively representing the frequency shifted version of discrete-time signal 104, each component of the differential discrete-time sub-signal representing the frequency shifted version of analog radio frequency signal 102 sampled with a sampling rate corresponding to a frequency of the analog radio frequency signal 102.

In an operational form, the sampler 121 is a current integrating sampler for sampling current. The sampler 121 can be represented by a continuous-time (CT) sinc filter with a first notch at 1/Ti with sampling time (Ti) and anti-aliasing for foldover frequencies. The sampling frequency may correspond to the input-output rate. In discrete-time (DT) signal processing input charge qᵢₙ[n] is considered as the input sampled signal and output voltage Vₒᵤₜ[n] is considered as the output sampled signal according to the following equations:

$${q}_{in} [ n ] = {\int }_{{nT}_{s}}^{{nT}_{s} + {T}_{i}} {i}_{in} ( t ) d t$$

$${V}_{out} [ n ] = \frac{{q}_{in} [ n ]}{{C}_{s}} .$$

In an operational form, the predetermined sampling rate fs is an oversampling rate with an oversampling factor that is 4, i.e., the predetermined sampling rate fₛ corresponds to four times the frequency of the local oscillator fₛ=4 f_{LO}.

In an operational form, the in-phase path 110 is configured to generate an in-phase oscillator signal 114 with the repeating function [1 0 −1 0]. In an operational form, the quadrature path 112 is configured to generate a quadrature oscillator signal 116 with the repeating function [0 1 0−1]. In an operational form, the in-phase path 110 is configured to generate an in-phase oscillator signal 114 with the repeating function [1 1+√2 1+√2 1 −1 −1−√2 −1−√2 −1]. In an operational form, the quadrature path 112 is configured to generate a quadrature oscillator signal 116 with the repeating function [−1−√2 −1 1 1+√2 1+√2 1 −1 −1−√2].

In an operational form, the processing circuit 103 comprises an in-phase path 118 coupled to the in-phase path 110 of the sampling mixer 101 and a quadrature path 120 coupled to the quadrature path 112 of the sampling mixer 101.

In an operational form, the processing circuit 103 comprises a discrete-time filter 105 configured to filter the intermediate discrete-time signal 108 at the predetermined sampling rate fₛ. The discrete-time filter 105 is a low-pass filter or band-pass filter, in particular a complex band-pass filter. In an operational form, the processing circuit 103 is configured to perform a charge sharing (not shown) between an in-phase and a quadrature component of the intermediate discrete-time signal 108. In an operational form, the processing circuit 103 comprises a switched capacitor circuit. In an operational form, the intermediate frequency is zero within a zero frequency region.

In an operational form, the sampling mixer 101 can be considered as a quad DT mixer operating at quadruple (4×) rate. The quadruple (4×) sampling concept is for keeping the original sample rate in the subsequent stage, thereby avoiding early decimation. In an operational form, further IIR filters are added before decimation.

In an operational form, the radio frequency receiver 100 is integrated on a single chip without using external filters.

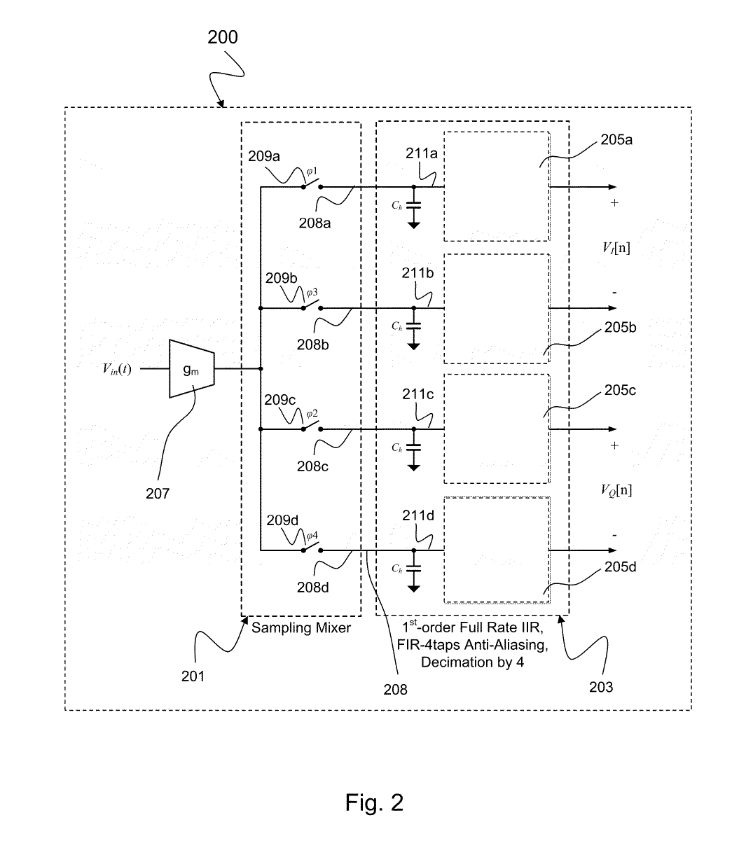

FIG. 2 shows a block diagram of a radio frequency receiver 200 according to an implementation form. The radio frequency receiver 200 is configured for receiving an analog radio frequency signal Vin(t). The radio frequency receiver 200 comprises a sampling mixer 201, a processing circuit 203, and an analog amplifier 207. The analog amplifier 207 together with the sampling mixer 201 comprises a windowed current integration mixer with beneficial filtering properties.

The radio frequency receiver 200 may correspond to the radio frequency receiver 100 described with respect to FIG. 1. In particular, the analog amplifier 207 may correspond to the analog amplifier 107, the sampling mixer 201 may correspond to the sampling mixer 101 and the processing circuit 203 may correspond to the processing circuit 103.

The sampling mixer 201 is configured to sample the analog radio frequency signal Vin(t) using a predetermined sampling rate fₛ to obtain a discrete-time sampled signal, and to shift the discrete-time sampled signal towards an intermediate frequency to obtain an intermediate discrete-time signal 208 sampled at the predetermined sampling rate fₛ. The processing circuit 203 is configured for discrete-time processing of the intermediate discrete-time signal 208 at the predetermined sampling rate fₛ.

The analog amplifier 207 is configured to receive and amplify the analog radio frequency signal Vin(t) corresponding to the analog amplifier 107 described with respect to FIG. 1. The sampling mixer 201 is coupled to the analog amplifier 207 and is configured to receive the amplified analog radio frequency signal from the analog amplifier 207.

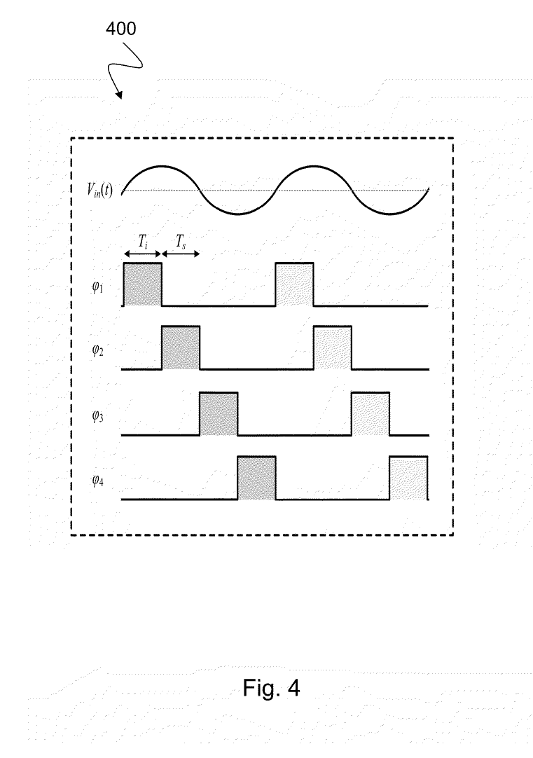

The sampling mixer 201 is a quadruple mixer, also called quad mixer or 4×-mixer comprising a first path 208a, a second path 208b, a third path 208c and a fourth path 208d. The sampling mixer 201 comprises a first switch 209a for controlling the first path 208a by a first control signal φ1, a second switch 209b for controlling the second path 208b by a second control signal φ2, a third switch 209c for controlling the third path 208c by a third control signal φ3 and a fourth switch 209d for controlling the fourth path 208d by a fourth control signal φ4. A representation of the control signals φ1, φ2, φ3 and φ4 is described with respect to FIG. 4.

The processing circuit 203 comprises a first path 211a connected to the first path 208a of the sampling mixer 201, a second path 211b connected to the second path 208b of the sampling mixer 201, a third path 211c connected to the third path 208c of the sampling mixer 201 and a fourth path 211d connected to the fourth path 208d of the sampling mixer 201 such that the intermediate discrete-time signal 208 passes from the paths 208a, 208b, 208c and 208d of the sampling mixer 201 to the respective paths 211a, 211b, 211c and 211d of the processing circuit 203. Each of the paths 211a, 211b, 211c, and 211d of the processing circuit 203 comprises a capacitor Cₕ shunted to ground and a respective filter 205a, 205b, 205c, 205d coupled into the respective path 208a, 208b, 208c, and 208d of the processing circuit 203 in a cascaded manner.

In an operational form, each of the respective paths 211a, 211b, 211c, 211d of the processing circuit 203 respectively forms together with the respective filter 205a, 205b, 205c, 205d in a first-order full-rate IIR low-pass filter. In an operational form, each of the paths 211a, 211b, 211c, 211d provides together with the respective filter 205a, 205b, 205c of the processing circuit 203 the transfer function described by:

$$H ( z ) = \frac{{V}_{out} ( z )}{{q}_{in} ( z )} = \frac{\frac{1}{{C}_{h} + {C}_{s}}}{1 - \frac{{C}_{h}}{{C}_{h} + {C}_{s}} {z}^{- 1}} ,$$

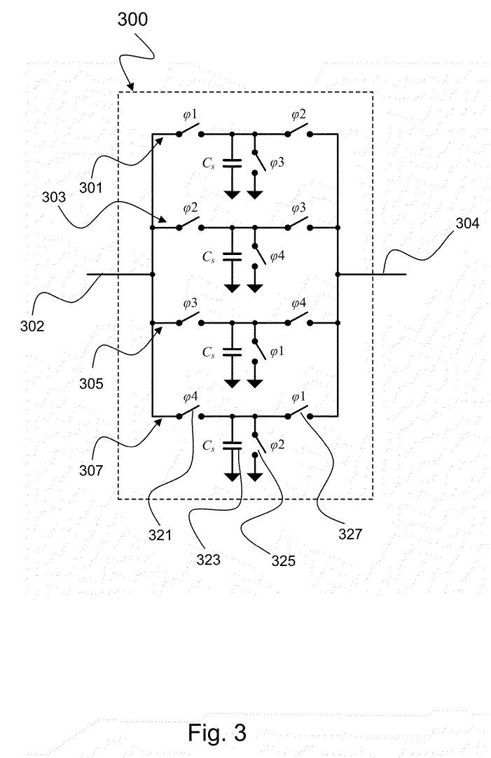

with Cs as a shunting capacitor (e.g. as shown in FIG. 3).

FIG. 3 shows a block diagram of a discrete-time filter 300 of a processing circuit of a radio frequency receiver according to an operational form. The discrete-time filter 300 may correspond to one of the filters 205a, 205b, 205c, and 205d as described with respect to FIG. 2. Alternatively, it could be used at lower frequencies in the IF section. The discrete-time filter 300 comprises a first filter path 301, a second filter path 303, a third filter path 305 and a fourth filter path 307, which are coupled in parallel between an input 302 and an output 304 of the discrete-time filter 300. Each of these four filter paths 301, 303, 305 and 307 comprise a first switch 321 serially coupled into the filter path, an input of the first switch 321 coupled to an input of the discrete-time filter 300, a capacitor 323, Cs shunting an output of the first switch 321 to ground, a second switch 325 for performing a charge reset coupled with its input to an output of the first switch 321 and with its output to ground and a third switch 327 coupled between an input of the second switch 325 and an output of the discrete-time filter 300.

The sampling rate at the input 302 can be described as fₛ₋ᵢₙ−1/Tₛ with sampling interval Tₛ and the sampling rate at each of the sub-paths 301, 303, 305 and 307 can be described as f_{s-sub}=(1/Tₛ)/4, i.e. a decimation by 4 can be used. However, since the sub-path outputs are combined in a time-staggered manner, the original data rate is restored.

The discrete-time filter 300 depicted in FIG. 3 represents only one out of two components of the discrete-time filters 103 described with respect to FIG. 1 where the first one of these components is used for filtering the in-phase path while the second one is used for filtering the quadrature path. The discrete-time filter 300 could be a single-ended version of a differential or pseudo-differential structure. Alternatively, the discrete-time filter 300 depicted in FIG. 3 represents one of the four components 205a, 205b, 205c, and 205d described with respect to FIG. 2.

FIG. 4 shows a graph 400 with a set of switching signals for controlling the switches of a discrete-time filter according to an operational form. A first control signal φ1 is a pulsed signal with pulse time Ti and sample time Ts. A second control signal φ2 is a pulsed signal with pulse time Ti and sample time Ts. A third control signal φ3 is a pulsed signal with pulse time Ti and sample time Ts. A fourth control signal φ4 is a pulsed signal with pulse time Ti and sample time Ts. In this implementation, the sample time Ts corresponds to the pulse time Ti. The pulses of the four control signals are time shifted with respect to each other's pulse time Ti. When the first control signal φ1 falls from high signal level to low signal level, i.e. the pulse is ending, the second control signal φ2 rises from low signal level to high signal level, i.e. the pulse is starting. The same condition holds for the relation between the second φ2 and the third φ3 pulse signal, the third φ3 and the fourth φ4 pulse signal and the fourth φ4 and the first φ1 pulse signal.

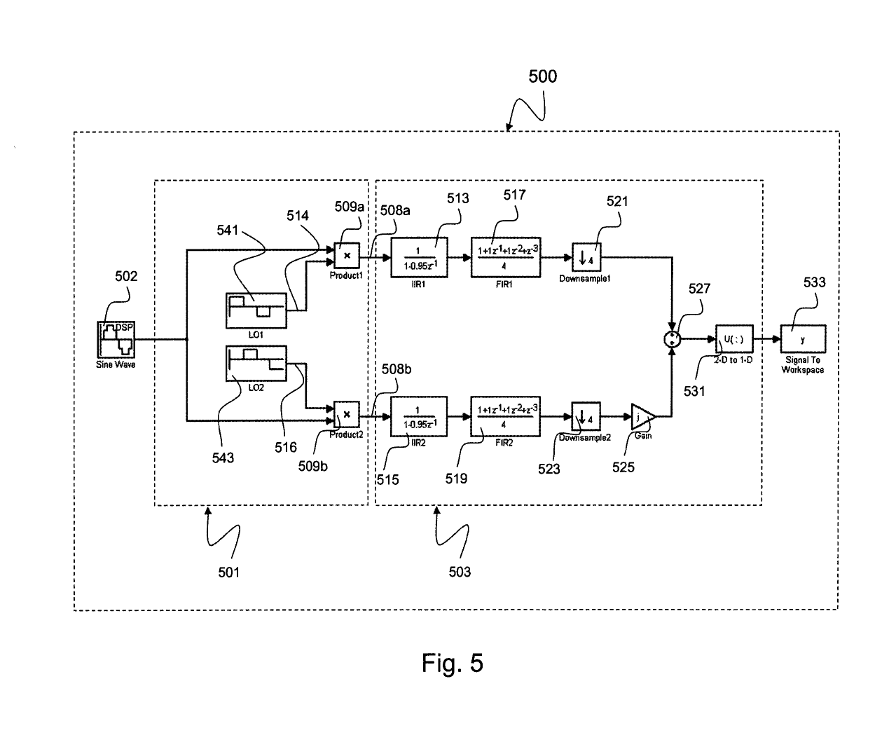

FIG. 5 shows a SIMULINK™ model 500 of a radio frequency receiver according to an operational form. The SIMULINK™ model comprises a sampling mixer 501 and a processing circuit 503 for modeling the sampling mixer 201 and the processing circuit 203 as described with respect to FIG. 2. A sine wave signal generator 502 provides a sine wave input signal to the sampling mixer 501. The sampling mixer 501 comprises a quadrature mixer with in-phase component 509a and quadrature component 509b and a local oscillator with in-phase component 541 for providing an in-phase signal 514 to the quadrature mixer's in-phase component 509a and with quadrature component 543 for providing a quadrature signal 516 to the quadrature mixer's quadrature component 509b. In an operational form, the in-phase component 541 of the quadrature mixer provides the in-phase signal [1,0,−1,0] 514 and the quadrature component 543 of the quadrature mixer provides the quadrature signal [0,1,0,−1] 516. The quadrature mixer 541, 543 multiplies the in-phase signal 514 with the sine wave generated by the sine wave signal generator 502 providing an in-phase output signal 508a and multiplies the quadrature signal 516 with the sine wave of the sine wave signal generator 502 providing a quadrature output signal 508b.

The in-phase signal 514 and the quadrature signal 516 represent the in-phase oscillator signal 114 and the quadrature oscillator signal 116 as described with respect to FIG. 1. The in-phase output signal 508a and the quadrature output signal 508b represent the intermediate discrete-time signal 108 as described with respect to FIG. 1.

The processing circuit 503 comprises an in-phase input coupled to an in-phase path of the processing circuit 503 for receiving the in-phase output signal 508a of the sampling mixer 501 and a quadrature input coupled to a quadrature path of the processing circuit 503 for receiving the quadrature output signal 508b of the sampling mixer 501.

The in-phase path of the processing circuit 503 comprises a first IIR filter 513, a first FIR filter 517, and a first downsampler 521. The quadrature path of the processing circuit 503 comprises a second IIR filter 515, a second FIR filter 519, a second downsampler 523 and a gain stage 525 (j=exp(pi/2) operator). The in-phase output signal 508a passes the first IIR filter 513, the first FIR filter 517 and the first downsampler 521 and is summed in a summer 527 with the quadrature output signal 508b having passed the second IIR filter 515, the second FIR filter 519, the second downsampler 523 and the gain stage 525. The summer 527 provides an output signal, which is converted in further conversion devices 531, 533 in a suitable signal representation.

In an operational form, the transfer function in z-domain representation IIR1(z) of the first IIR filter 513 is IIR1(z)=1/(1−0.95z⁻¹) and the transfer function in z-domain representation IIR2(z) of the second IIR filter 515 is IIR2(z)=1/(1−0.95z⁻¹). In an operational form, the transfer function in z-domain representation FIR1(z) of the first FIR filter 517 is FIR1(z)=(1+z⁻¹+z⁻²+z⁻³)/4 and the transfer function in z-domain representation FIR2(z) of the second FIR filter 519 is FIR2(z)=(1+z⁻¹+z⁻²+z⁻³)/4. In an operational form, the first and second downsamplers 521 and 523 use a downsampling factor of 4.

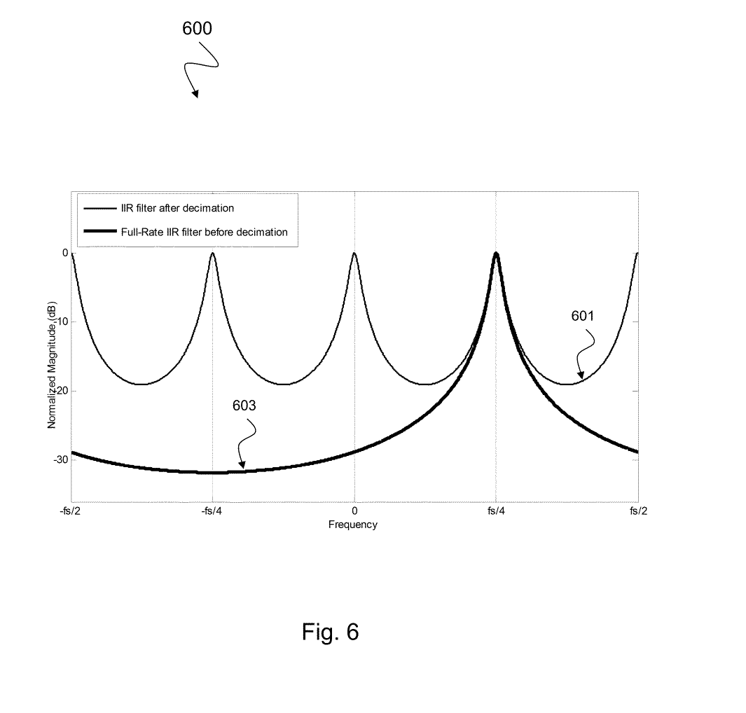

FIG. 6 shows a performance diagram 600 of a radio frequency receiver according to an operational form. The diagram 600 depicts an IIR filter output signal 601 of a conventional RF receiver where IIR filtering is performed after decimation, i.e. the IIR filter output signal 601 carries images resulting from decimation. The diagram 600 further depicts an IIR filter output signal 603 of a radio frequency receiver according to aspects of the invention where IIR filtering is performed prior to decimation, e.g. the output signal of the first IIR filter 513 of the sampling mixer 501 described with respect to FIG. 5. The performance of the IIR filter output signal 603 of a radio frequency receiver according to aspects of the invention with respect to the IIR filter output signal 601 of a conventional RF receiver is increased by a factor of about 30 dB at and around the alias frequencies 0, −fs/4 and −fs/2.

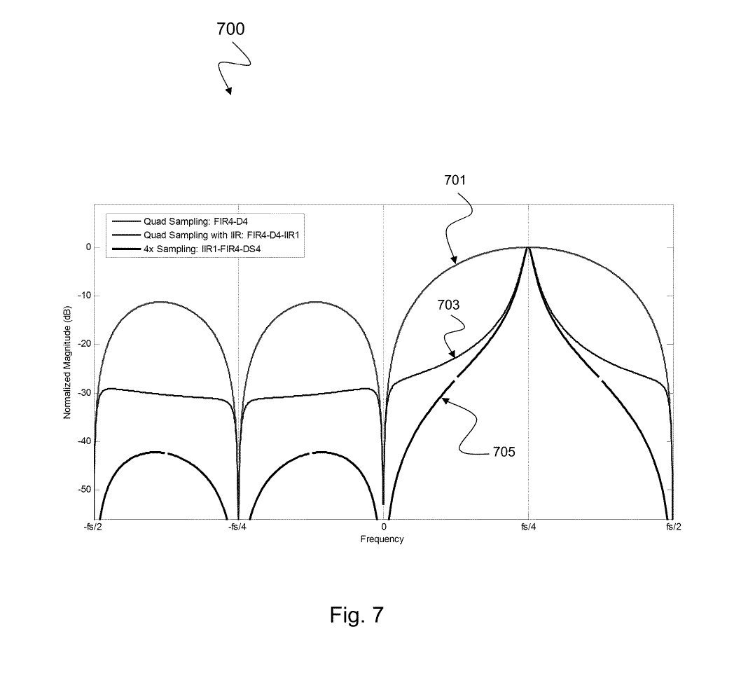

FIG. 7 shows a performance diagram 700 of a radio frequency receiver according to an operational form. The diagram 700 depicts a first output signal 701 of a conventional RF receiver applying FIR filtering and downsampling. The diagram 700 depicts a second output signal 703 of a conventional RF receiver applying FIR filtering, downsampling and IIR filtering, wherein the IIR filtering is after the downsampling. The diagram 700 depicts a third output signal 705 of a radio frequency receiver according to aspects of the invention applying FIR filtering, IIR filtering and downsampling, wherein the downsampling is after the FIR filtering and after the IIR filtering. The performance of the third output signal 705 of a radio frequency receiver according to aspects of the invention is increased with respect to the first output signal 701 of a conventional RF receiver by a factor of at least 30 dB and with respect to the second output signal 703 of a conventional RF receiver by a factor of at least 10 to 15 dB at and around the alias frequencies 0, −fs/4 and −fs/2 with respect to the downsampling. The notches of the third output signal 705 show a wider bandwidth than the notches of the first and second output signals 701 and 703.

FIG. 8 shows a block diagram of an analog amplifier 800 of a radio frequency receiver in continuous-time representation according to an operational form. The analog amplifier 800 comprises an optional first capacitor 801, a gₘ stage 803, a sampling switch 805 and a second capacitor 807. The first capacitor 801 is coupled to an input of the analog amplifier 800 and shunts the input to ground. The gₘ stage 803 is coupled with its input to the input of the analog amplifier 800 and with its output to the sampling switch 805. The sampler 805 is coupled with its output to an output of the analog amplifier 800. The output of the analog amplifier 800 is shunted by the second capacitor 807 to ground.

The analog amplifier 800 may correspond to the analog amplifier 107 or to the analog amplifier 207 as described with respect to FIG. 1 and FIG. 2.

FIG. 9 shows a block diagram of an analog amplifier 900 of a radio frequency receiver in discrete-time representation according to an operational form. An input signal x[n] passes a D-to-C converter 901, a Zero Order Hold (ZOH) unit 903, a filter 905 and a sampling switch 907 and is transformed by those functional units to an output signal y[n]. The transformation can be expressed by the following equations:

$$x ( t ) = x [ n ] for n {T}_{s} \leq t < ( n + 1 ) {T}_{s}$$

$$h ( t ) = {g}_{m} / {C}_{s} for 0 \leq t < {T}_{s}$$

$$y [ n ] = {\int }_{n {T}_{s}}^{( n + 1 ) {T}_{s}} x ( t ) d t = \frac{{g}_{m} {T}_{s}}{{C}_{s}} x [ n ] .$$

Thus, the analog amplifier 900 corresponds to a gₘ stage representing a discrete-time (DT) gain.

The analog amplifier 900 may correspond to the analog amplifier 107 or to the analog amplifier 207 as described with respect to FIG. 1 and FIG. 2.

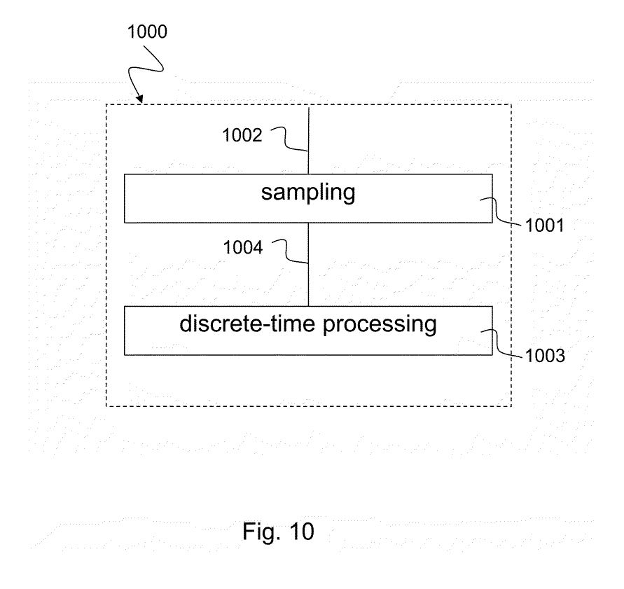

FIG. 10 shows a schematic diagram of a method 1000 for receiving an analog radio frequency signal according to an operational form. The method 1000 comprises sampling 1001 an analog radio frequency signal 1002 using a predetermined sampling rate fs to obtain a discrete-time sampled signal, and shifting the discrete-time sampled signal towards an intermediate frequency to obtain an intermediate discrete-time signal 1004 sampled at the predetermined sampling rate fs. The method 1000 further comprises discrete-time processing 1003 and the intermediate discrete-time signal 1004 at the predetermined sampling rate fs.

What is claimed is:

1. A radio frequency receiver for receiving an analog radio frequency signal, the radio frequency receiver comprising:
a sampling mixer configured to:
sample the analog radio frequency signal using a predetermined sampling rate (fₛ) to obtain a discrete-time signal; and
shift the discrete-time signal towards an intermediate frequency (|f_{RF}−f_{LO}|) to obtain an intermediate discrete-time signal sampled at the fₛ; and
a processing circuit configured to discrete-time processing the intermediate discrete-time signal at the fₛ.

2. The radio frequency receiver according to claim 1, wherein the fₛ is an oversampling rate with an oversampling factor which is at least 2 with respect to a frequency (f_{LO}) of a local oscillator of the sampling mixer.

3. The radio frequency receiver according to claim 1, wherein the fₛ is an oversampling rate with an oversampling factor which is at least 4 with respect to a frequency (f_{LO}) of a local oscillator of the sampling mixer.

4. The radio frequency receiver according to claim 1, wherein the sampling mixer is a direct-sampling mixer.

5. The radio frequency receiver according to claim 1, wherein the sampling mixer is configured to oversample the analog radio frequency signal with an oversampling rate and to provide a number of discrete-time sub-signals collectively representing the discrete-time signal, and wherein each discrete-time sub-signal represents the analog radio frequency signal sampled with a sampling rate corresponding to a frequency of a local oscillator.

6. The radio frequency receiver according to claim 1, wherein the sampling mixer is a quadrature mixer comprising an in-phase path and a quadrature path.

7. The radio frequency receiver according to claim 6, wherein the in-phase path is configured to generate an in-phase oscillator signal with the repeating function [1 0 −1 0], and wherein the quadrature path is configured to generate a quadrature oscillator signal with the repeating function [0 1 0−1].

8. The radio frequency receiver according to claim 6, wherein the in-phase path is configured to generate an in-phase oscillator signal with the repeating function [1 1+√2 1+√2 1 −1 −1−√2 −1−√2 −1], and wherein the quadrature path is configured to generate a quadrature oscillator signal with the repeating function [−1−√2 −1 1 1+√2 1 +√2 1 −1 −1−√2].

9. The radio frequency receiver according to claim 1, wherein the processing circuit comprises:
an in-phase path coupled to an in-phase path of the sampling mixer; and
a quadrature path coupled to a quadrature path of the sampling mixer.

10. The radio frequency receiver according to claim 1, wherein the processing circuit comprises a channel selector.

11. The radio frequency receiver according to claim 1, wherein the processing circuit comprises a discrete-time filter being configured to filter the intermediate discrete-time signal at the fₛ.

12. The radio frequency receiver according to claim 11, wherein the discrete-time filter is a low-pass filter or band-pass filter, in particular a complex band-pass filter.

13. The radio frequency receiver according to claim 1, wherein the processing circuit is configured to perform a charge sharing between an in-phase and a quadrature component of the intermediate discrete-time signal.

14. The radio frequency receiver according to claim 1, wherein the processing circuit comprises a switched capacitor circuit.

15. The radio frequency receiver according to claim 1, wherein the intermediate frequency is zero within a zero frequency region.

16. The radio frequency receiver according to claim 1, further comprising an analog amplifier arranged upstream from the sampling mixer.

17. A method for receiving an analog radio frequency signal, the method comprising:
sampling the analog radio frequency signal using a predetermined sampling rate (fs) to obtain a discrete-time signal;
shifting the discrete-time signal towards an intermediate frequency to obtain an intermediate discrete-time signal sampled at the fₛ; and
discrete-time processing the intermediate discrete-time signal at the fₛ.

18. A computer program product comprising instructions stored on a non-transitory storage medium, wherein the instructions cause a processor to:
sample an analog radio frequency signal using the fₛ to obtain a discrete-time signal;
shift the discrete-time signal towards an intermediate frequency to obtain an intermediate discrete-time signal sampled at the fₛ; and
discrete-time process the intermediate discrete-time signal at the fₛ.
